(19) United States
(12) Patent Application Publication
(10) Pub. No.: US 2026/0171165 A1
(43) Pub. Date: Jun. 18, 2026

(54) VOLTAGE SUPPLY CIRCUIT AND SEMICONDUCTOR MEMORY DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Atsushi SUZUKI, Funabashi Chiba (JP); Osamu HIRABAYASHI, Suginami Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/297,042

(22) Filed: Aug. 12, 2025

(30) Foreign Application Priority Data
Dec. 13, 2024 (JP) 2024-218950

(51) Int. Cl. G11C 16/30; H02M 1/14; H02M 3/07

(52) U.S. Cl. CPC G11C 16/30; H02M 1/14; H02M 3/07

(57) ABSTRACT

A voltage supply circuit includes: a first LDO amplifier circuit that receives a power supply voltage from a power supply and outputs a first control voltage from a first output section in response to a preset reference voltage; a second LDO amplifier circuit that receives the power supply voltage from the power supply and outputs a second control voltage from a second output section in response to the reference voltage; an oscillator circuit; a first charge pump circuit that outputs a first output voltage generated from the first control voltage to a first output terminal; a second charge pump circuit that outputs a second output voltage generated from the second control voltage to a second output terminal; and a control circuit that controls operation of the first LDO amplifier circuit and the second LDO amplifier circuit.

### CROSS-REFERENCE TO RELATED APPLICATIONS

This application is based upon and claims the benefit of priority from the prior Japanese Patent Application No. 2024-218950, filed on Dec. 13, 2024 the entire contents of which are incorporated herein by reference.

### FIELD

This embodiment relates to a voltage supply circuit.

### BACKGROUND

Conventionally, there is a voltage supply circuit equipped with a charge pump circuit that supplies boosted voltage for each operation of a semiconductor memory device such as a flash memory.

In such a voltage supply circuit, if the range of voltages supplied to the charge pump circuit is wide, ripple in the output voltage of the charge pump circuit can become a problem.

### BRIEF DESCRIPTION OF THE DRAWINGS

FIG. 1 is a diagram showing an example of the configuration of a voltage supply circuit according to a first embodiment.

FIG. 2 is a diagram for explaining the load response characteristics of the first and second LDO circuits according to the first embodiment.

FIG. 3 is a diagram showing an example of a simulation result of the characteristics of a first output voltage VO1 during programming and erasing.

FIG. 4 is a diagram showing an example of a simulation result of the characteristics of a second output voltage VO2 during programming and erasing.

FIG. 5 is a diagram showing an example of a simulation result of the characteristics of a second output voltage VO2 during reading.

FIG. 6 is a diagram showing an example of the configuration of a semiconductor memory device according to a third embodiment.

FIG. 7 is a diagram showing an example of the configuration of a voltage supply circuit according to a second embodiment.

FIG. 8A is a diagram for explaining the load response characteristics of a second LDO circuit according to the second embodiment.

FIG. 8B is a diagram for explaining the load response characteristics of a third LDO circuit according to the second embodiment.

FIG. 9 shows an example of a simulation result of the characteristics of the second output voltage VO2 during reading.

### DETAILED DESCRIPTION

An object of one embodiment is to provide a voltage supply circuit that can suppress the effect of changes in power supply voltage on the voltage supplied to the charge pump circuit and reduce ripples in the output voltage of the charge pump circuit.

A voltage supply circuit according to the embodiment, includes:
a first LDO amplifier circuit that receives a power supply voltage from a power supply and outputs a first control voltage from a first output section in response to a preset reference voltage;
a second LDO amplifier circuit that receives the power supply voltage from the power supply and outputs a second control voltage from a second output section in response to the reference voltage;
an oscillator circuit that generates and outputs a clock signal;
a first charge pump circuit that receives the first control voltage, operates based on the clock signal, and outputs a first output voltage generated from the first control voltage to a first output terminal;
a second charge pump circuit that receives the second control voltage, operates based on the clock signal, and outputs a second output voltage generated from the second control voltage to a second output terminal; and
a control circuit that controls operation of the first LDO amplifier circuit and the second LDO amplifier circuit.

The voltage supply circuit according to the embodiment will be described in detail below with reference to the attached drawings. Note that the present invention is not limited to these embodiments.

### First Embodiment

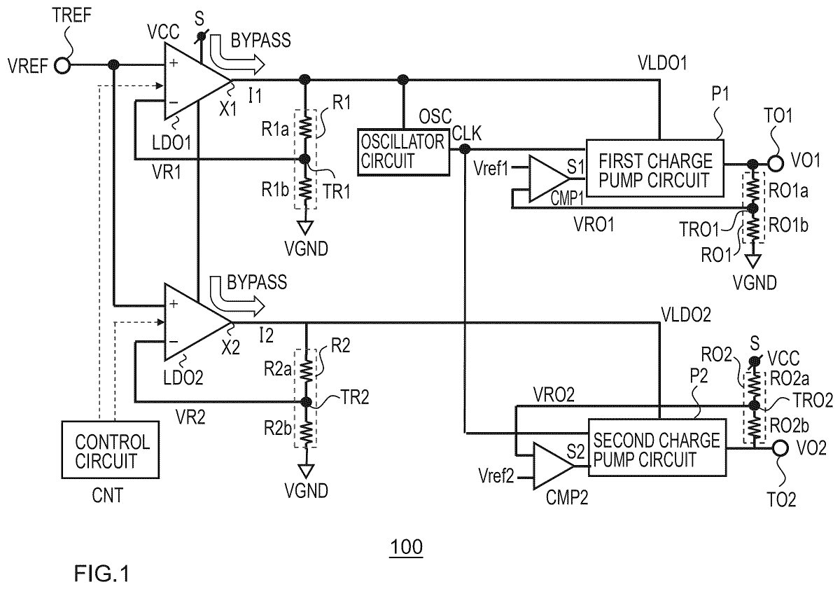

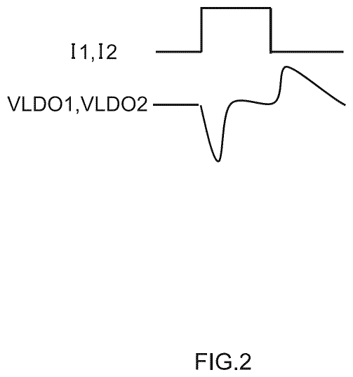

FIG. 1 is a diagram showing an example of the configuration of a voltage supply circuit according to a first embodiment. FIG. 2 is a diagram for explaining the load response characteristics of the first and second LDO circuits according to the first embodiment.

### [Voltage Supply Circuit]

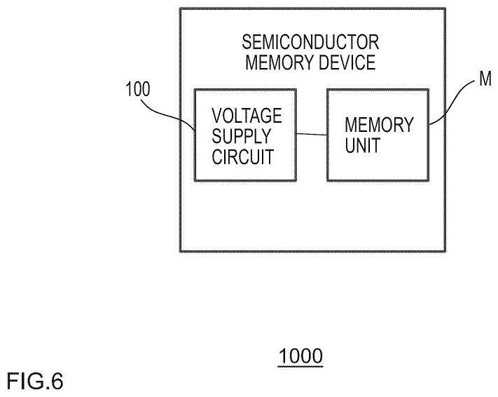

The voltage supply circuit 100 according to the first embodiment is a circuit for supplying a predetermined voltage to the memory unit M of the semiconductor memory device 1000 shown in FIG. 6.

As shown in FIG. 1, for example, the voltage supply circuit 100 includes a first LDO (Low Drop Out) amplifier circuit LDO1, a second LDO amplifier circuit LDO2, an oscillator circuit OSC, a first charge pump circuit P1, a second charge pump circuit P2, a control circuit CNT, a first LDO voltage dividing circuit R1, a second LDO voltage dividing circuit R2, a first output voltage dividing circuit RO1, a second output voltage dividing circuit RO2, a first comparator CMP1, and a second comparator CMP2.

The components of the voltage supply circuit 100 are described in detail below.

### [First LDO Voltage Dividing Resistor]

The first LDO voltage dividing circuit R1 is connected between the first output X1 of the first LDO amplifier circuit LDO1 and the ground potential VGND, as shown in FIG. 1.

This first LDO voltage dividing circuit R1, for example as shown in FIG. 1, is configured to output a first LDO divided voltage VR1 obtained by dividing the voltage between the first output section X1 of the first LDO amplifier circuit LDO1 and the ground potential VGND by a first LDO voltage division ratio from a first LDO output voltage dividing terminal TR1.

This first LDO voltage dividing circuit R1 includes, for example, a first LDO voltage dividing resistor R1a and a second LDO voltage dividing resistor R1b, as shown in FIG. 1.

The first LDO voltage dividing resistor R1a has one end connected to the output section X1 of the first LDO amplifier circuit LDO1, and the other end connected to the first LDO output voltage dividing terminal TR1, as shown in FIG. 1, for example.

Furthermore, the second LDO voltage dividing resistor R1b has, for example, one end connected to the first LDO output voltage dividing terminal TR1 and the other end connected to the ground potential VGND, as shown in FIG. 1.

### [Second LDO Voltage Dividing Circuit]

The second LDO voltage dividing circuit R2 is connected between the second output X2 of the second LDO amplifier circuit LDO2 and the ground potential VGND, for example, as shown in FIG. 1.

This second LDO voltage dividing circuit R2, for example as shown in FIG. 1, is configured to output a second LDO divided voltage VR2 obtained by dividing the voltage between the second output section X2 of the second LDO amplifier circuit LDO2 and the ground potential VGND by a second LDO voltage division ratio from the second LDO output voltage dividing terminal TR2.

This second LDO voltage dividing circuit R2 includes, for example, a third LDO voltage dividing resistor R2a and a fourth LDO voltage dividing resistor R2b, as shown in FIG. 1.

The third LDO voltage dividing resistor R2a has one end connected to the second output part X2 of the second LDO amplifier circuit LDO2, and the other end connected to the second LDO output voltage dividing terminal TR2.

Furthermore, the fourth LDO voltage dividing resistor R2b has one end connected to the second LDO output voltage dividing terminal TR2 and the other end connected to the ground potential VGND.

### [First LDO Amplifier Circuit]

The first LDO amplifier circuit LDO1 is supplied with a power supply voltage VCC from a power supply S, as shown in FIG. 1, and outputs a first control voltage VLDO1 from a first output section X1 according to a preset reference voltage VREF and the first LDO divided voltage VR1 described above.

In particular, the first LDO amplifier circuit LDO1 controls the first control voltage VLDO1 so that the first LDO divided voltage VR1, which is obtained by dividing the first control voltage VLDO1 by the first voltage division ratio using the first LDO voltage dividing circuit R1, approaches the reference voltage VREF.

### [Second LDO Amplifier Circuit]

The second LDO amplifier circuit LDO2 is supplied with a power supply voltage VCC from a power supply S, as shown in FIG. 1, and outputs a second control voltage VLDO2 from a second output section X2 according to a reference voltage VREF and the second LDO divided voltage VR2 described above.

In particular, the second LDO amplifier circuit LDO2 controls the second control voltage VLDO2 so that the second LDO divided voltage VR2, which is obtained by dividing the second control voltage VLDO2 by the second voltage division ratio using the second LDO voltage dividing circuit R2, approaches the reference voltage VREF.

In this way, first and second LDO amplifier circuits LDO1, LDO2 are provided corresponding to the first and second charge pump circuits P1, P2, respectively. As a result, the load currents I1, I2 output by the first and second LDO amplifier circuits LDO1, LDO2 do not interfere with each other, and the first and second output sections X1, X2 do not require capacitance to suppress overshoot of the first and second control voltages VLDO1, VLDO2.

Also, as shown in FIG. 2, the first and second LDO amplifier circuits LDO1 and LDO2 are set to have slow load response characteristics.

The load response of the first LDO amplifier circuit LDO1 and the second LDO amplifier circuit LDO2 can be controlled to be slow by setting the drive currents that drive the first LDO amplifier circuit LDO1 and the second LDO amplifier circuit LDO2 to small values.

### [Oscillator Circuit]

The oscillator circuit OSC is supplied with the first control voltage VLDO1 output by the first LDO amplifier circuit LDO1.

The oscillator circuit OSC generates a clock signal CLK for setting the boost operation, and outputs the clock signal CLK to the first charge pump circuit P1 and the second charge pump circuit P2.

### [First Output Voltage Dividing Circuit]

The first output voltage dividing circuit RO1 is connected between the first output terminal TO1 and the ground potential VGND, as shown in FIG. 1.

The first output voltage dividing circuit RO1 is configured to output a first output divided voltage VRO1 from the first output voltage dividing terminal TRO1, which is obtained by dividing the voltage between the first output terminal TO1 and the ground potential VGND by the first output voltage dividing ratio.

The first output voltage dividing circuit RO1 includes, for example, a first output voltage dividing resistor RO1a and a second output voltage dividing resistor RO1b, as shown in FIG. 1.

The first output voltage dividing resistor RO1a has one end connected to the first output terminal TO1 and the other end connected to the first output voltage dividing terminal TRO1.

Furthermore, the second output voltage dividing resistor RO1b has one end connected to the first output voltage dividing terminal TRO1 and the other end connected to the ground potential VGND.

### [Second Output Voltage Dividing Circuit]

The second output voltage dividing circuit RO2 is connected between the second output terminal TO2 and the power supply S, for example, as shown in FIG. 1.

The second output voltage dividing circuit RO2 divides the voltage between the second output terminal TO2 and the power supply S into a second output divided voltage VRO2 by a second output voltage division ratio, and outputs this second output divided voltage VRO2 from the second output voltage dividing terminal TRO2.

This second output voltage dividing circuit RO2 includes, for example, a third output voltage dividing resistor RO2a and a fourth output voltage dividing resistor RO2b, as shown in FIG. 1.

The third output voltage dividing resistor RO2b has one end connected to the second output terminal TO2 and the other end connected to the second output voltage dividing terminal TRO2.

Furthermore, the fourth output voltage dividing resistor RO2a has one end connected to the second output voltage dividing terminal TRO2 and the other end connected to the power supply S.

### [First Comparator]

The first comparator CMP1 outputs a first feedback signal S1, to the first charge pump circuit P1, according to the result of comparing the first reference voltage Vref1 with the first output divided voltage VRO1.

### [Second Comparator]

The second comparator CMP2 outputs a second feedback signal S2, to the second charge pump circuit P2, according to the result of comparing the second reference voltage Vref2 with the second output divided voltage VRO2.

### [First Charge Pump Circuit]

The first charge pump circuit P1 is supplied with a first control voltage VLDO1, and operates (boosts the voltage to the positive side) based on the clock signal CLK and the first feedback signal S1, and outputs a first output voltage VO1 generated from the first control voltage VLDO1 to the first output terminal TO1.

In other words, the first output voltage VO1 is a positive voltage higher than the ground potential VGND.

The first charge pump circuit P1 adjusts the first output voltage VO1 based on the first feedback signal S1 so that the first output divided voltage VRO1 approaches the first reference voltage Vref1.

For example, when the first feedback signal S1 indicates that the first output divided voltage VRO1 is less than the first reference voltage Vref1, the first charge pump circuit P1 performs a positive boost operation to increase the first output voltage VO1.

On the other hand, the first charge pump circuit P1 stops boosting when the first feedback signal S1 indicates that the first output divided voltage VRO1 is equal to or greater than the first reference voltage Vref1.

### [Second Charge Pump Circuit]

The second charge pump circuit P2 is supplied with a second control voltage VLDO2, and operates (boosts to the negative side) based on the clock signal CLK and the second feedback signal S2, and outputs a second output voltage VO2 generated from the second control voltage VLDO2 to the second output terminal TO2.

In other words, the second output voltage VO2 is a negative voltage lower than the ground potential VGND.

The second charge pump circuit P2 adjusts the second output voltage VO2 based on the second feedback signal S2 so that the second output divided voltage VRO2 approaches the second reference voltage Vref2.

For example, when the second feedback signal S2 indicates that the second output divided voltage VRO2 is equal to or greater than the second reference voltage Vref2, the second charge pump circuit P2 performs a negative boost operation to lower the second output voltage VO2.

On the other hand, the second charge pump circuit P2 stops boosting operation when the second feedback signal S2 indicates that the second output divided voltage VRO2 is less than the second reference voltage Vref2.

### [Control Circuit]

The control circuit CNT controls the operation of the first LDO amplifier circuit LDO1, the second LDO amplifier circuit LDO2, the oscillator circuit OSC, the first charge pump circuit P1, and the second charge pump circuit P2.

For example, in a preset first mode, the control circuit CNT causes the first LDO amplifier circuit LDO1 to output a first control voltage VLDO1 from the first output part X1 in response to the reference voltage VREF.

Furthermore, in the first mode, the control circuit CNT causes the second LDO amplifier circuit LDO2 to output a second control voltage VLDO2 from the second output section X2.

On the other hand, in a preset second mode different from the first mode, the control circuit CNT forcibly causes the first LDO amplifier circuit LDO1 to bypass the power supply voltage VCC supplied from the power supply S and output the power supply voltage VCC from the first output part X1 as the first control voltage VLDO1, regardless of the reference voltage VREF.

Furthermore, in the second mode, the control circuit CNT causes the second LDO amplifier circuit LDO2 to bypass the power supply voltage VCC supplied from the power supply S and output the power supply voltage VCC from the second output part X2 as a second control voltage VLDO2.

The control circuit CNT may also be configured to control the load response of the first LDO amplifier circuit LDO1 and the second LDO amplifier circuit LDO2 in the first mode to be slower than the load response of the first LDO amplifier circuit LDO1 and the second LDO amplifier circuit LDO2 in the second mode.

For example, in the first mode, the control circuit CNT controls the load response of the first LDO amplifier circuit LDO1 and the second LDO amplifier circuit LDO2 to be slowed down by reducing the drive currents that drive the first LDO amplifier circuit LDO1 and the second LDO amplifier circuit LDO2, respectively.

On the other hand, in the second mode, the control circuit CNT controls the load response of the first LDO amplifier circuit LDO1 and the second LDO amplifier circuit LDO2 to be faster by increasing the drive currents that drive the first LDO amplifier circuit LDO1 and the second LDO amplifier circuit LDO2, respectively.

The first mode is, for example, a mode in which the memory unit M of the semiconductor memory device 1000 shown in FIG. 6 described below performs a program operation or an erase operation.

On the other hand, the second mode is, for example, a mode in which the memory unit M of the semiconductor memory device 1000 shown in FIG. 6 described below executes a read operation.

Here, the load capacitance of the semiconductor memory device 1000 when the memory unit M of the semiconductor memory device 1000 is performing a read operation is greater than the load capacitance of the semiconductor memory device 1000 when the memory unit M of the semiconductor memory device 1000 is performing a program operation or an erase operation.

In other words, the load capacitance of the memory unit M of the semiconductor memory device 1000 connected to the first output terminal TO1 and the second output terminal TO2 in the second mode is set to be larger than the load capacitance of the memory unit M of the semiconductor memory device 1000 connected to the first output terminal TO1 and the second output terminal TO2 in the first mode.

The control circuit CNT controls the first reference voltage Vref1 so that the value of the first output voltage VO1 output by the first charge pump circuit P1 is set to a target value defined for each of the first and second modes.

Furthermore, the control circuit CNT controls the second reference voltage Vref2 so that the value of the second output voltage VO2 output by the second charge pump circuit P2 is set to a target value defined for each of the first and second modes.

### [Operation Characteristics of Voltage Supply Circuit]

Next, the operation characteristics of the voltage supply circuit 100 having the above configuration will be described.

As described above, in the first mode, the control circuit CNT causes the first LDO amplifier circuit LDO1 to output the first control voltage VLDO1 from the first output part X1 in response to the reference voltage VREF.

Furthermore, in the first mode, the control circuit CNT causes the second LDO amplifier circuit LDO2 to output the second control voltage VLDO2 from the second output section X2.

On the other hand, in the second mode, the control circuit CNT forcibly causes the first LDO amplifier circuit LDO1 to bypass the power supply voltage VCC supplied from the power supply S and output the power supply voltage VCC from the first output part X1 as the first control voltage VLDO1, regardless of the reference voltage VREF.

Furthermore, in the second mode, the control circuit CNT causes the second LDO amplifier circuit LDO2 to bypass the power supply voltage VCC supplied from the power supply S and output the power supply voltage VCC from the second output part X2 as the second control voltage VLDO2.

Also, as described above, the first and second LDO amplifier circuits LDO1 and LDO2 are set to have slow load response characteristics.

As described above, the first charge pump circuit P1 is supplied with the first control voltage VLDO1, operates based on the clock signal CLK and the first feedback signal S1, and outputs the first output voltage VO1 generated from the first control voltage VLDO1 to the first output terminal TO1.

Furthermore, as described above, the second charge pump circuit P2 is supplied with the second control voltage VLDO2, operates based on the clock signal CLK and the second feedback signal S2, and outputs the second output voltage VO2 generated from the second control voltage VLDO2 to the second output terminal TO2.

By the operation of the voltage supply circuit 100 as described above, predetermined first and second output voltages VO1, VO2 are output in the first and second modes.

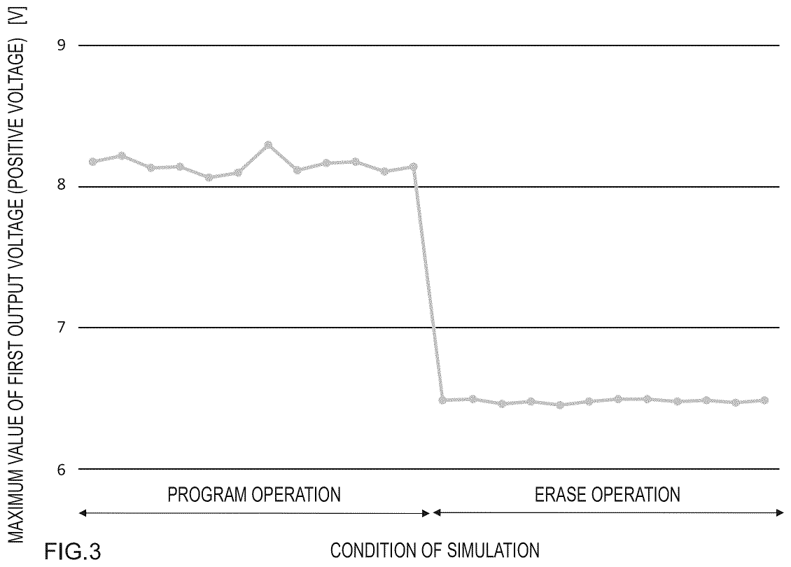

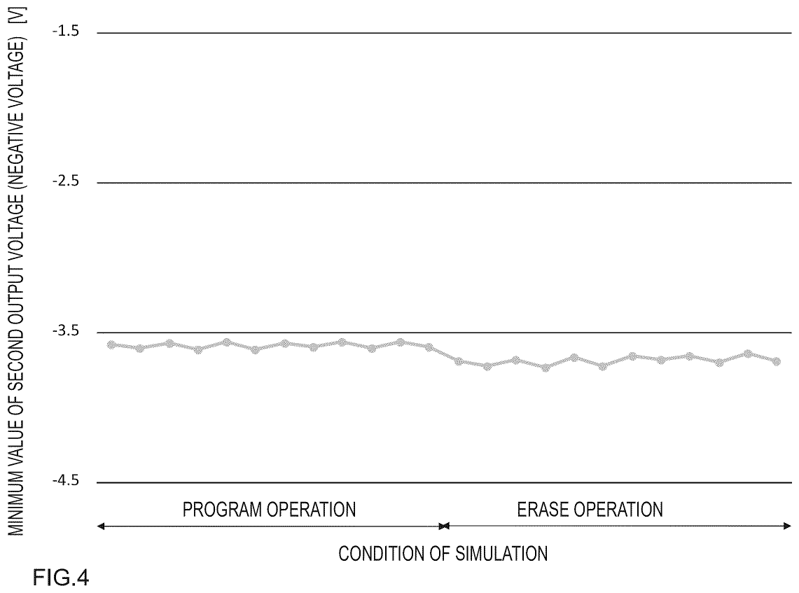

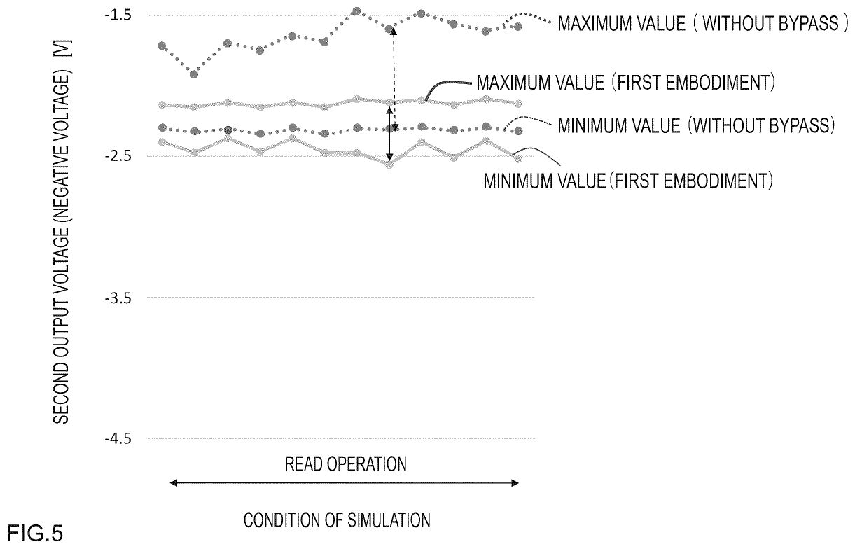

Here, FIG. 3 is a diagram showing an example of a simulation result of the characteristics of a first output voltage VO1 during programming and erasing. FIG. 4 is a diagram showing an example of a simulation result of the characteristics of a second output voltage VO2 during programming and erasing. FIG. 5 is a diagram showing an example of a simulation result of the characteristics of a second output voltage VO2 during reading.

It is noted that FIG. 3 shows the relationship between the maximum value of the first output voltage VO1 and the conditions for each program operation and erase operation. FIG. 4 shows the relationship between the minimum value of the second output voltage VO2 and the conditions for each program operation and erase operation.

As shown in FIGS. 3 and 4, the simulation results of the characteristics of the first and second output voltages VO1, VO2 during programming and erasing confirmed that in the voltage supply circuit 100 according to the first embodiment, the ripples of the first and second output voltages VO1, VO2 can be reduced by providing the first and second LDO amplifier circuits LDO1, LDO2 that generate the voltage supplied to the first and second charge pump circuits P1, P2.

That is, in the voltage supply circuit 100 according to the first embodiment, during a program operation and an erase operation (first mode), the ripple voltage can be reduced by using the first and second LDO amplifier circuits LDO1 and LDO2, which have a slow load response.

Also, as shown in FIG. 5, a simulation result of the characteristics of the second output voltage VO2 confirmed that, during read operation (second mode), it is possible to respond to sudden current changes by bypassing the power supply voltage VCC to the first and second output parts X1, X2 of the first and second LDO amplifier circuits LDO1, LDO2. Furthermore, it was confirmed that, during read operation (second mode), the load capacitance of the memory unit M of the semiconductor memory device 1000 is large, so that the ripple voltage of the second output voltage VO2 can be reduced.

In this way, during read operations, a mode is provided in which the power supply voltage is bypassed at the output of the LDO amplifier circuit, which corresponds to the read operation of the flash memory macro, and by reducing the ripple voltage, capacitance is not required at the output of the LDO amplifier circuit and the output of the charge pump circuit.

In other words, in the voltage supply circuit 100 according to the first embodiment, the effect of changes in the power supply voltage on the voltage supplied to the charge pump circuit can be suppressed, thereby reducing the ripple in the output voltage of the charge pump circuit.

### [Semiconductor Memory Device]

Here, FIG. 6 is a diagram showing an example of the configuration of a semiconductor memory device to which the voltage supply circuit 100 according to the first embodiment is applied.

The semiconductor memory device 1000 includes a memory unit M and a voltage supply circuit 100, as shown in FIG. 6. The semiconductor memory device 1000 is, for example, a flash memory such as a NOR type flash memory.

The memory unit M includes a memory cell array of a flash memory.

In addition, the voltage supply circuit 100 is configured to supply a predetermined voltage to the memory unit M of the semiconductor memory device 1000.

In this way, the voltage supply circuit 100 is provided in the semiconductor memory device 1000.

As described above, the voltage supply circuit 100 supplies a first output voltage VO1 and a second output voltage VO2 from a first output terminal TO1 and a second output terminal TO2 shown in FIG. 1 to the memory unit M, which performs data program operations, erase operations, and read operations of the semiconductor memory device 1000.

As described above, in the first mode, the control circuit CNT causes the first LDO amplifier circuit LDO1 to output the first control voltage VLDO1 from the first output section X1 in response to the reference voltage VREF.

Furthermore, in the first mode, the control circuit CNT causes the second LDO amplifier circuit LDO2 to output the second control voltage VLDO2 from the second output part X2.

On the other hand, in the second mode, the control circuit CNT forcibly causes the first LDO amplifier circuit LDO1 to bypass the power supply voltage VCC supplied from the power supply S and output the power supply voltage VCC from the first output part X1 as the first control voltage VLDO1, regardless of the reference voltage VREF.

Furthermore, in the second mode, the control circuit CNT causes the second LDO amplifier circuit LDO2 to bypass the power supply voltage VCC supplied from the power supply S and output the power supply voltage VCC from the second output part X2 as the second control voltage VLDO2.

The first mode is, for example, a mode in which the memory unit M of the semiconductor memory device 1000 shown in FIG. 6 described below performs a program operation or an erase operation.

On the other hand, the second mode is, for example, a mode in which the memory unit M of the semiconductor memory device 1000 performs a read operation.

Then, as already mentioned, the load capacitance when the memory unit M of the semiconductor memory device 1000 is performing a read operation is greater than the load capacitance of the semiconductor memory device 1000 when the memory unit M of the semiconductor memory device 1000 is performing a program operation or an erase operation.

In other words, the load capacitance of the memory unit M of the semiconductor memory device 1000 connected to the first output terminal TO1 and the second output terminal TO2 in the second mode is set to be larger than the load capacitance of the memory unit M of the semiconductor memory device 1000 connected to the first output terminal TO1 and the second output terminal in the first mode.

Therefore, as described above, in the voltage supply circuit 100, during a read operation (second mode), steep current changes can be accommodated by bypassing the power supply voltage VCC to the first and second output parts X1, X2 of the first and second LDO amplifier circuits LDO1, LDO2. Furthermore, during a read operation, since the load capacity of the memory unit M of the semiconductor memory device 1000 is large, the ripple voltage of the second output voltage VO2 can be reduced.

In other words, according to the semiconductor memory device 1000 to which the voltage supply circuit 100 of the first embodiment is applied, the effect of changes in the power supply voltage on the voltage supplied to the charge pump circuit can be suppressed, and the ripple in the output voltage of the charge pump circuit can be reduced, so that program operations, erase operations, and read operations can be more appropriately performed in the memory unit M of the semiconductor memory device 1000.

### Second Embodiment

Here, in the first embodiment described above, an example of the configuration of the voltage supply circuit was explained. However, the configuration of this voltage supply circuit is not limited to this. Therefore, in this second embodiment, another example of the configuration of the voltage supply circuit will be explained.

In the following, in the description of the voltage supply circuit according to the second embodiment, the description of the configuration of the voltage supply circuit that is given the same reference numerals as in the first embodiment will be omitted.

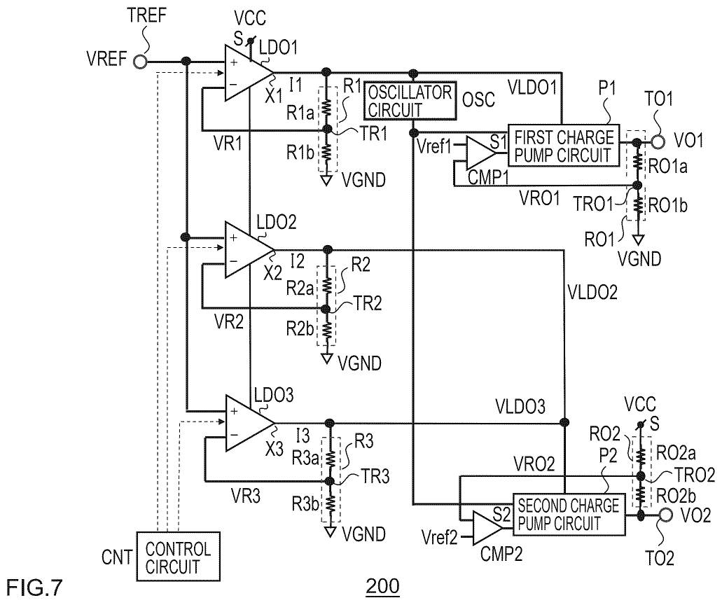

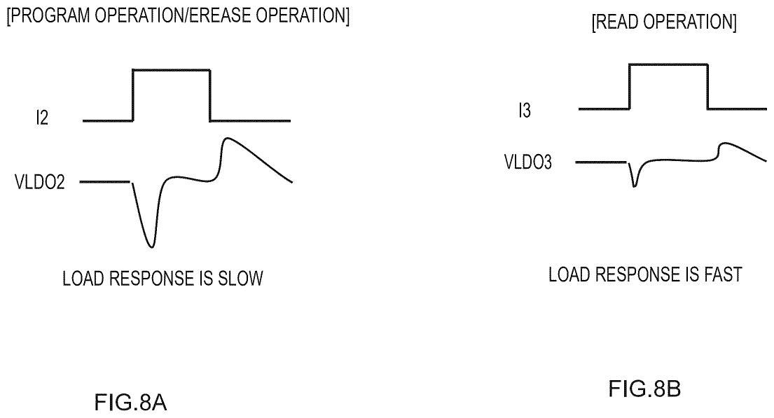

Here, FIG. 7 is a diagram showing an example of the configuration of a voltage supply circuit according to a second embodiment. FIG. 8A is a diagram for explaining the load response characteristics of a second LDO circuit according to the second embodiment. FIG. 8B is a diagram for explaining the load response characteristics of a third LDO circuit according to the second embodiment.

It is noted that FIG. 8A shows the load response characteristics during a program operation and an erase operation. FIG. 8B shows the load response characteristics during a read operation.

### [Voltage Supply Circuit]

For example, as shown in FIG. 7, the voltage supply circuit 200 according to the second embodiment further includes a third LDO amplifier circuit LDO3 and a third LDO voltage dividing circuit R3, in comparison with the configuration of the voltage supply circuit 100 according to the first embodiment shown in FIG. 1.

### [Third LDO Voltage Dividing Circuit]

The third LDO voltage dividing circuit R3 is connected between the third output X3 of the third LDO amplifier circuit LDO3 and the ground potential VGND, for example, as shown in FIG. 7.

This third LDO voltage dividing circuit R3, for example as shown in FIG. 7, is configured to output a third LDO divided voltage VR3 obtained by dividing the voltage between the third output section X3 of the third LDO amplifier circuit LDO3 and the ground potential VGND by the third LDO voltage division ratio from the third LDO output voltage dividing terminal TR3.

This third LDO voltage dividing circuit R3 includes, for example, a fifth LDO voltage dividing resistor R3a and a sixth LDO voltage dividing resistor R3b, as shown in FIG. 7.

The fifth LDO voltage dividing resistor R3a has one end connected to the third output part X3 of the third LDO amplifier circuit LDO3, and the other end connected to the third LDO output voltage dividing terminal TR3.

The sixth LDO voltage dividing resistor R3b has one end connected to the third LDO output voltage dividing terminal TR3 and the other end connected to the ground potential VGND.

### [Third LDO Amplifier Circuit]

The third LDO amplifier circuit LDO3 is supplied with a power supply voltage VCC from a power supply S, and outputs a third control voltage VLDO3 from a third output section X3 according to a reference voltage VREF.

In particular, the third LDO amplifier circuit LDO3 controls the third control voltage VLDO3 so that the third divided voltage VR3, which is obtained by dividing the third control voltage VLDO3 by a third voltage division ratio using the third LDO voltage dividing circuit R3, approaches the reference voltage VREF.

Here, in the voltage supply circuit 200 according to the second embodiment, the second charge pump circuit P2 is supplied with the second control voltage VLDO2 or the third control voltage VLDO3, operates based on the clock signal CLK, and outputs the second output voltage VO2 generated from the second control voltage VLDO2 or the third control voltage VLDO3 to the second output terminal TO2.

In the second embodiment, the control circuit CNT controls the operation of the first LDO amplifier circuit LDO1, the second LDO amplifier circuit LDO2, and the third LDO amplifier circuit LDO3.

In a preset first mode, the control circuit CNT causes the first LDO amplifier circuit LDO1 to output a first control voltage VLDO1 from a first output part X1 according to a reference voltage VREF, causes the second LDO amplifier circuit LDO2 to output a second control voltage VLDO2 from a second output part X2, and stops the operation of the third LDO amplifier circuit LDO3.

On the other hand, in a preset second mode different from the first mode, the control circuit CNT causes the first LDO amplifier circuit LDO1 to output a first control voltage VLDO1 from a first output part X1 according to the reference voltage VREF, causes the third LDO amplifier circuit LDO2 to output a third control voltage VLDO3 from a third output part X3, and stops the operation of the second LDO amplifier circuit LDO2.

Here, the load response (FIG. 8A) of the second LDO amplifier circuit LDO2, which operates during a program operation and an erase operation (first mode) and outputs a second control voltage VLDO2, is set to be slower than the load response (FIG. 8B) of the third LDO amplifier circuit LDO3, which operates during a read operation (second mode) and outputs a third control voltage VLDO3.

The rest of the configuration and operation of the voltage supply circuit 200 of the second embodiment is the same to the configuration and operation of the voltage supply circuit 100 of the first embodiment.

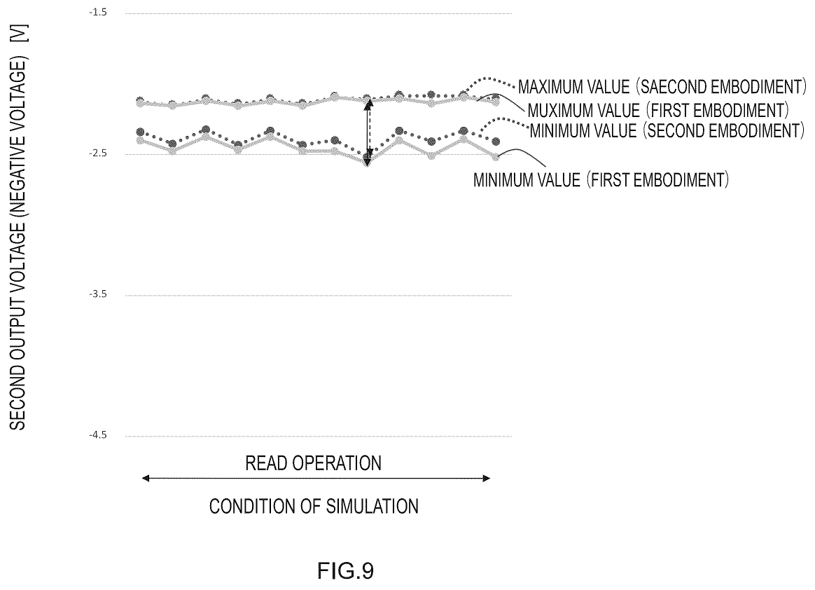

Here, FIG. 9 shows an example of a simulation result of the characteristics of the second output voltage VO2 during reading.

As shown in FIG. 9, a simulation result of the characteristics of the second output voltage VO2 during read operation confirmed that in the voltage supply circuit 200 according to the second embodiment, the third LDO amplifier circuit LDO3, which has a fast load response, can be used during read operation (second mode) to accommodate steep current changes. Furthermore, it was confirmed that the load capacity of the memory unit M of the semiconductor memory device 1000 is large during read operation (second mode), so that the ripple voltage of the second output voltage VO2 can be reduced.

As described above, in the voltage supply circuit 200 according to the second embodiment, the second charge pump circuit P2 is supplied with either the second or third control voltage VLDO2, VLDO3 output by the second and third LDO amplifier circuits LDO2, LDO3. Then, the control circuit CNT switches between the third LDO amplifier circuit LDO3, which has a fast load response, and the second LDO amplifier circuit LDO2, which has a slow load response, depending on the current profile of the second charge pump circuit P2.

This makes it possible to handle read operations (second mode) that require a fast load response, and by reducing the ripple voltage, it becomes unnecessary to have capacitance at the output of the LDO amplifier circuit and the output of the charge pump circuit.

As described above, the voltage supply circuit according to the second embodiment can suppress the effect of changes in the power supply voltage on the voltage supplied to the charge pump circuit, thereby reducing the ripple in the output voltage of the charge pump circuit.

The voltage supply circuit 200 according to the second embodiment, like the voltage supply circuit 100 according to the first embodiment, is also applied to the semiconductor memory device 1000 shown in FIG. 6 described above.

In other words, according to the semiconductor memory device 1000 applying the voltage supply circuit 200 of the second embodiment, the effect of changes in the power supply voltage on the voltage supplied to the charge pump circuit can be suppressed, thereby reducing the ripple in the output voltage of the charge pump circuit.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A voltage supply circuit comprising:
a first LDO amplifier circuit that receives a power supply voltage from a power supply and outputs a first control voltage from a first output section in response to a preset reference voltage;
a second LDO amplifier circuit that receives the power supply voltage from the power supply and outputs a second control voltage from a second output section in response to the reference voltage;
an oscillator circuit that generates and outputs a clock signal;
a first charge pump circuit that receives the first control voltage, operates based on the clock signal, and outputs a first output voltage generated from the first control voltage to a first output terminal;
a second charge pump circuit that receives the second control voltage, operates based on the clock signal, and outputs a second output voltage generated from the second control voltage to a second output terminal; and
a control circuit that controls operation of the first LDO amplifier circuit and the second LDO amplifier circuit.

2. The voltage supply circuit according to claim 1,
wherein
in a preset first mode, the control circuit causes the first LDO amplifier circuit to output the first control voltage from the first output section and the second LDO amplifier circuit to output the second control voltage from the second output section in response to the reference voltage, and
on the other hand, in a preset second mode different from the first mode, the control circuit forcibly causes the first LDO amplifier circuit to bypass the power supply voltage supplied from the power supply and output the power supply voltage as the first control voltage from the first output section, regardless of the reference voltage, and causes the second LDO amplifier circuit to bypass the power supply voltage supplied from the power supply and output the power supply voltage as the second control voltage from the second output section.

3. The voltage supply circuit according to claim 2,
wherein the control circuit controls the load response of the first LDO amplifier circuit and the second LDO amplifier circuit in the first mode to be slower than the load response of the first LDO amplifier circuit and the second LDO amplifier circuit in the second mode.

4. The voltage supply circuit according to claim 3,
wherein
the control circuit controls the load response of the first LDO amplifier circuit and the second LDO amplifier circuit to be slower by reducing the drive current driving the first LDO amplifier circuit and the second LDO amplifier circuit in the first mode, and
on the other hand, the control circuit controls the load response of the first LDO amplifier circuit and the second LDO amplifier circuit to be faster by increasing the drive current driving the first LDO amplifier circuit and the second LDO amplifier circuit in the second mode.

5. The voltage supply circuit according to claim 1,
wherein the voltage supply circuit is provided in a semiconductor memory device, and
wherein the voltage supply circuit supplies the first output voltage and the second output voltage from the first output terminal and the second output terminal to a memory section that executes data program operations, erase operations, and read operations of the semiconductor memory device.

6. The voltage supply circuit according to claim 5,
wherein the first mode is a mode in which the memory unit of the semiconductor memory device performs a program operation or an erase operation, and
wherein the second mode is a mode in which the memory unit of the semiconductor memory device performs a read operation.

7. The voltage supply circuit according to claim 6, wherein
the load capacitance of the memory section of the semiconductor memory device connected to the first output terminal and the second output terminal in the second mode is greater than the load capacitance of the memory section of the semiconductor memory device connected to the first output terminal and the second output terminal in the first mode.

8. The voltage supply circuit according to claim 1, further comprising a third LDO amplifier circuit that receives the power supply voltage from the power supply and outputs a third control voltage from a third output section according to the reference voltage,
wherein the second charge pump circuit receives the second control voltage or the third control voltage, operates based on the clock signal, and outputs a second output voltage generated from the second control voltage or the third control voltage to a second output terminal, and
wherein the control circuit controls the operation of the first LDO amplifier circuit, the second LDO amplifier circuit, and the third LDO amplifier circuit.

9. The voltage supply circuit according to claim 8, wherein the load response of the second LDO amplifier circuit is slower than the load response of the third LDO amplifier circuit.

10. The voltage supply circuit according to claim 9,
wherein
in a preset first mode, the control circuit causes the first LDO amplifier circuit to output the first control voltage from the first output section, causes the second LDO amplifier circuit to output the second control voltage from the second output section, and stops the operation of the third LDO amplifier circuit, in accordance with the reference voltage,
on the other hand, in a preset second mode different from the first mode, the control circuit causes the first LDO amplifier circuit to output the first control voltage from the first output section, causes the third LDO amplifier circuit to output the third control voltage from the third output section, and stops the operation of the second LDO amplifier circuit, in accordance with the reference voltage.

11. The voltage supply circuit of claim 1, wherein the first output voltage is a positive voltage higher than the ground potential, and the second output voltage is a negative voltage lower than the ground potential.

12. A semiconductor memory device comprising:
a memory unit that includes a memory cell array of a flash memory, and
a voltage supply circuit that supplies a voltage to the memory unit,
wherein the voltage supply circuit comprises:
a first LDO amplifier circuit that receives a power supply voltage from a power supply and outputs a first control voltage from a first output section in response to a preset reference voltage;
a second LDO amplifier circuit that receives the power supply voltage from the power supply and outputs a second control voltage from a second output section in response to the reference voltage;
an oscillator circuit that generates and outputs a clock signal;
a first charge pump circuit that receives the first control voltage, operates based on the clock signal, and outputs a first output voltage generated from the first control voltage to a first output terminal;
a second charge pump circuit that receives the second control voltage, operates based on the clock signal, and outputs a second output voltage generated from the second control voltage to a second output terminal; and
a control circuit that controls operation of the first LDO amplifier circuit and the second LDO amplifier circuit.

13. The semiconductor memory device according to claim 12,
wherein
in a preset first mode, the control circuit causes the first LDO amplifier circuit to output the first control voltage from the first output section and the second LDO amplifier circuit to output the second control voltage from the second output section in response to the reference voltage, and
on the other hand, in a preset second mode different from the first mode, the control circuit forcibly causes the first LDO amplifier circuit to bypass the power supply voltage supplied from the power supply and output the power supply voltage as the first control voltage from the first output section, regardless of the reference voltage, and causes the second LDO amplifier circuit to bypass the power supply voltage supplied from the power supply and output the power supply voltage as the second control voltage from the second output section.

14. The semiconductor memory device according to claim 13,
wherein the control circuit controls the load response of the first LDO amplifier circuit and the second LDO amplifier circuit in the first mode to be slower than the load response of the first LDO amplifier circuit and the second LDO amplifier circuit in the second mode.

15. The semiconductor memory device according to claim 14,
wherein
the control circuit controls the load response of the first LDO amplifier circuit and the second LDO amplifier circuit to be slower by reducing the drive current driving the first LDO amplifier circuit and the second LDO amplifier circuit in the first mode, and
on the other hand, the control circuit controls the load response of the first LDO amplifier circuit and the second LDO amplifier circuit to be faster by increasing the drive current driving the first LDO amplifier circuit and the second LDO amplifier circuit in the second mode.

16. The semiconductor memory device according to claim 12,
wherein the voltage supply circuit is provided in a semiconductor memory device, and
wherein the voltage supply circuit supplies the first output voltage and the second output voltage from the first output terminal and the second output terminal to a memory section that executes data program operations, erase operations, and read operations of the semiconductor memory device.

17. The semiconductor memory device according to claim 16,
wherein the first mode is a mode in which the memory unit of the semiconductor memory device performs a program operation or an erase operation, and
wherein the second mode is a mode in which the memory unit of the semiconductor memory device performs a read operation.

18. The semiconductor memory device according to claim 17,
wherein
the load capacitance of the memory section of the semiconductor memory device connected to the first output terminal and the second output terminal in the second mode is greater than the load capacitance of the memory section of the semiconductor memory device connected to the first output terminal and the second output terminal in the first mode.

19. The semiconductor memory device according to claim 12, further comprising a third LDO amplifier circuit that receives the power supply voltage from the power supply and outputs a third control voltage from a third output section according to the reference voltage,
wherein the second charge pump circuit receives the second control voltage or the third control voltage, operates based on the clock signal, and outputs a second output voltage generated from the second control voltage or the third control voltage to a second output terminal, and
wherein the control circuit controls the operation of the first LDO amplifier circuit, the second LDO amplifier circuit, and the third LDO amplifier circuit.

20. The voltage supply circuit according to claim 19, wherein the load response of the second LDO amplifier circuit is slower than the load response of the third LDO amplifier circuit.
